(19) United States
(12) Patent Application Publication
(10) Pub. No.: US 2010/0085617 A1
(43) Pub. Date: Apr. 8, 2010

(54) Image Processing Apparatus and Image Recording Medium

(75) Inventor: Tomohiro Nakamura, Azumino-shi (JP)

Correspondence Address: HOGAN & HARTSON L.L.P., 1999 AVENUE OF THE STARS, SUITE 1400, LOS ANGELES, CA, 90067, US

(73) Assignee: SEIKO EPSON CORPORATION, Tokyo (JP)

(21) Appl. No.: 12/559,286

(22) Filed: Sep. 14, 2009

(30) Foreign Application Priority Data
Oct. 8, 2008 (JP) 2008-262175

(51) Int. Cl. G03F 3/08

(52) U.S. Cl. 358/518

(57) ABSTRACT

An image processing apparatus that performs processing for converting image data of an original document into data for an output apparatus is provided. The image processing apparatus includes: a correcting unit that applies a change to the image data so as to ensure that a color that is located in a region in a color space that represents color values of an image is outputted in one color of a recording material; and a corrected data outputting unit that outputs the image data corrected by the correcting unit. The region is defined by excluding a second region from a first region. The first region is a region that includes each color value obtained as a result of reading a sample by means of the reading apparatus. The second region is a region in which a color that should not be outputted as the one color is located.

### BACKGROUND

1. Technical Field

The present invention generally relates to an image processing apparatus, an image processing program, and the like that can be used for a copying machine. In particular, the invention relates to an image processing apparatus that is capable of reproducing, in a primary color, an image that is represented in the primary color in an original document while avoiding any color that should not be outputted as a primary color from being outputted as the primary color.

2. Related Art

A copying machine reads an image of an original document and reproduces the read image on other print target medium. In such document reading and image reproduction processing, the following data conversion processing is usually performed. As a first step, image data of an original document, which is acquired as a result of scanning and represented in the color representation format of a scanner (e.g., RGB color model), is converted into a format that represents absolute color values such as a Lab format. Next, the format of the converted absolute color-value data is further converted into the color representation format of a recording material (i.e., colorant) that is used by an output apparatus such as a printer. For example, the format of the converted data is converted into a CMYK color model format. Then, printing is executed on the basis of the CMYK-converted data. A color conversion table that is tailored to the characteristics of the apparatus is used in each of the first color conversion and the second color conversion, thereby achieving accurate and faithful color reproduction.

A color conversion apparatus for color printing that is capable of reproducing colors that make enhanced color impression on a user is disclosed in JP-A-10-200769. Specifically, a technique for shifting a hue (i.e., color phase) toward a side at which “color-mixture turbidity” is relatively small is disclosed therein. The color phase is shifted within a range in which the color-mixture turbidity is conspicuous when two or more printing inks are mixed with each other or one another. In addition, the color phase is shifted within a tolerable range so that the shifted hue does not excessively deviate from a human memory color.

However, the color conversion apparatus of the related art explained above has not addressed the following problems. Some errors might occur in the color conversion processes. In addition, the color conversion characteristics of an apparatus change due to aged deterioration. Therefore, there is a possibility that a deviation from a color of an original document occurs at the time of outputting. For this reason, other color is mixed at a part that is represented in a primary color (i.e., by a single-color recording material) in an original document. Consequently, the color of the part is outputted as turbid one, which does not look good. Moreover, when a scanner scans an original document, the state of a sheet such as texture and the like differs from one sheet area to another. Therefore, even when the color, of one sheet area of a scanned original document is the same as the color of another sheet area thereof, the scanner does not always recognize that they are the same color. That is, reading variation occurs. The reading error could cause the mixture of other color into an image that is supposed to be represented in an original primary color, which is not desirable.

On the other hand, there is a type of colors that is close to a primary color but should not be outputted as the primary color. An example of such a color is human flesh color. If the flesh color is outputted as a primary color, the quality of a reproduced image will be undesirably lower in comparison with the quality of an original image. Therefore, there is a demand for an apparatus that is capable of achieving both faithful reproduction of primary colors without color mixture and correct color output of non-primary colors, the latter of which should not be outputted as a primary color.

Although the unexamined patent application publication identified above discloses a useful color conversion technique for shifting a color phase toward a side at which color-mixture turbidity is relatively small, the related art disclosed therein has not provided a solution to fully overcome the foregoing problems yet.

### SUMMARY

An advantage of some aspects of the invention is to provide an image processing apparatus, an image processing program, and the like that can be used for a copying machine, and in particular, an image processing apparatus that is capable of reproducing, in a primary color, an image part that is represented in the primary color in an original document while avoiding any color that should not be outputted as a primary color from being outputted as the primary color.

In order to overcome the above-identified disadvantages without any limitation thereto, an image processing apparatus that performs processing for converting image data of an original document acquired by a reading apparatus into data for an output apparatus is provided. An image processing apparatus according to an aspect of the invention includes: a correcting section that applies a change to the image data so as to ensure that a color that is located in a predetermined region in a color space that represents color values of an image is outputted in one color of a recording material of the output apparatus; and a corrected data outputting section that outputs the image data corrected by the correcting section, wherein the predetermined region is defined by excluding a second region in the color space from a first region in the color space, the first region is a region that includes each color value obtained as a result of reading a sample by means of the reading apparatus, the sample including a plurality of printed patches of the one color, the printed patches having depths of shade that differ from one to another, and the second region is a region in which a predetermined color that should not be outputted as the one color is located.

In the configuration of an image processing apparatus according to the first aspect of the invention described above, it is preferable that the second region should be determined on the basis of each color value that is obtained as a result of reading a sample on which an image in the predetermined color is printed by means of the reading apparatus.

In the configuration of an image processing apparatus according to the first aspect of the invention described above, the predetermined region may be defined by excluding a part of the second region from the first region.

In the configuration of an image processing apparatus according to the first aspect of the invention described above, it is preferable that the one color and the predetermined color that should not be outputted as the one color should be yellow and flesh color, respectively.

In order to overcome the above-identified disadvantages without any limitation thereto, an image processing program for causing an image processing apparatus to perform processing for converting image data of an original document acquired by a reading apparatus into data for an output apparatus is provided. An image processing program according to a second aspect of the invention causes the image processing apparatus to execute: applying a change to the image data so as to ensure that a color that is located in a predetermined region in a color space that represents color values of an image is outputted in one color of a recording material of the output apparatus for correction; and outputting the corrected image data, wherein the predetermined region is defined by excluding a second region in the color space from a first region in the color space, the first region is a region that includes each color value obtained as a result of reading a sample by means of the reading apparatus, the sample including a plurality of printed patches of the one color, the printed patches having depths of shade that differ from one to another, and the second region is a region in which a predetermined color that should not be outputted as the one color is located.

Other objects, features, and advantages of the invention will be fully understood from the following detailed description of an exemplary embodiment of the invention read in conjunction with accompanying drawings.

### BRIEF DESCRIPTION OF THE DRAWINGS

The invention will be described with reference to the accompanying drawings, wherein like numbers reference like elements.

FIG. 1 is a block diagram that schematically illustrates an example of the configuration of a copying machine that is provided with an image processing apparatus according to an exemplary embodiment of the invention.

FIG. 2 is a diagram that schematically illustrates an example of a chart according to an exemplary embodiment of the invention.

FIG. 3 is a diagram that schematically illustrates an example of correction processing data according to an exemplary embodiment of the invention.

FIG. 4 is a diagram that schematically illustrates an example of the radius of the long axis of an ellipse and the radius of the short axis thereof for defining a base primary color region according to an exemplary embodiment of the invention.

FIG. 5 is a diagram that schematically illustrates an example of a defined base primary color region according to an exemplary embodiment of the invention.

FIG. 6 is a diagram that schematically illustrates an example of a graph that shows the relationship between a distance 1 and “a” according to an exemplary embodiment of the invention.

FIG. 7 is a diagram that schematically illustrates an example of Lab values of a color that should be excluded, which are projected on a b-L plane, according to an exemplary embodiment of the invention.

FIG. 8 is a diagram that schematically illustrates an example of a defined primary color region according to an exemplary embodiment of the invention.

FIG. 9 is a flowchart that schematically illustrates an example of the procedure of processing performed in copy processing according to an exemplary embodiment of the invention.

### DESCRIPTION OF EXEMPLARY EMBODIMENTS

With reference to the accompanying drawings, an exemplary embodiment of the invention will now be explained in detail. Needless to say, it should be noted that the exemplary embodiment of the invention described below is not intended to limit the technical scope of the invention. In the following description of this specification and the illustration in the accompanying drawings, the same reference numerals or the same reference signs are used for the same or similar components.

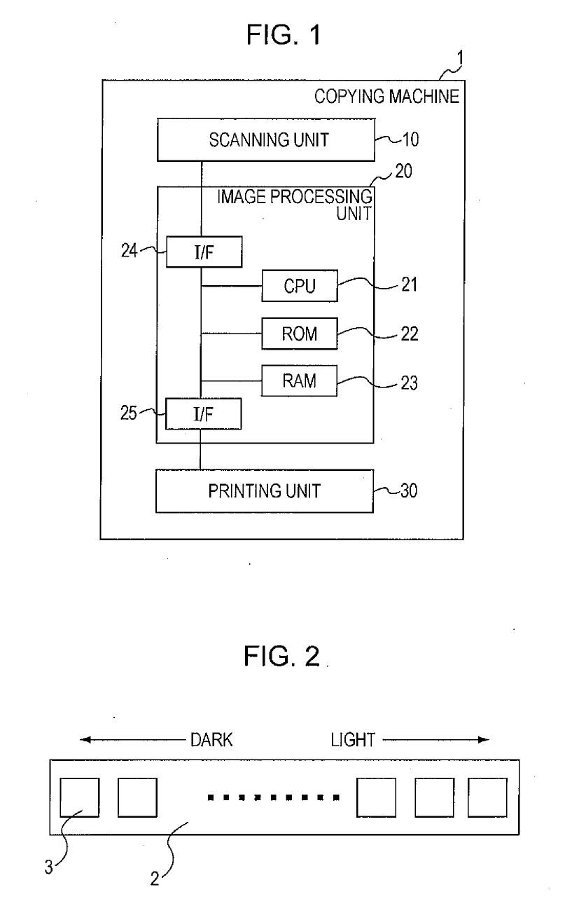

FIG. 1 is a block diagram that schematically illustrates an example of the configuration of a copying machine that is provided with an image processing apparatus according to an exemplary embodiment of the invention. An image processing unit 20 illustrated in FIG. 1 is an example of an image processing apparatus according to an aspect of the invention. The image processing unit 20 converts image data that is acquired by scanning an original document by means of a scanning unit 10 into print data that is used by a printing unit 30. The image processing unit 20 performs correction processing for the faithful reproduction of an image part that is represented in a primary color in an original document in the primary color and the correct color output of a non-primary color part that should not be outputted as a primary color, thereby achieving high-quality copying. A primary color region in a color space that should be outputted in a primary color when the printing unit 30 outputs a printed image is predefined without including any color that is close to a primary color but should not be outputted as the primary color. At the time of color-conversion processing, the correction processing is performed so as to ensure that all of colors that are included in the region are to be outputted in the primary color. With such correction processing, both faithful reproduction of primary colors and correct color output of non-primary colors are achieved.

As illustrated in FIG. 1, a copying machine 1 according to the present embodiment of the invention includes the scanning unit 10, the image processing unit 20, and the printing unit 30. The scanning unit 10 functions as a document reading apparatus. The image processing unit 20 performs the image processing that is briefly described above as an example of an image processing apparatus according to an aspect of the invention. The printing unit 30 functions as an output apparatus.

The scanning unit 10 is provided with a scanning mechanism and a scan control unit, both of which are not illustrated in FIG. 1. The scanning mechanism reads an original document. The scan control unit controls the reading operation of the scanning mechanism and creates image data from the scanned original document. The image data created by the scan control unit is gradation data in which each of a plurality of pixels that make up an image has a depth-of-shade tone value for each color component of red, green, and blue (RGB). The created image data is supplied to the image processing unit 20 as “scanner input data”.

As explained earlier, the image processing unit 20 converts the scanner input data supplied from the scanning unit 10 into “printer output data” that has a format available for print processing performed by the printing unit 30. The printer output data is output data supplied to the printing unit 30 for printing, which may be hereinafter reworded as “printing output data”. As illustrated in FIG. 1, the image processing unit 20 includes a CPU 21, a ROM 22, a RAM 23, an I/F 24, and another I/F 25. The I/F 24 is a unit for interfacing with the scanning unit 10. The I/F 25 is a unit for interfacing with the printing unit 30.

The CPU 21 performs data conversion processing. Specifically, the CPU 21 converts the scanner input data represented in an RGB color-model format into data of absolute color values (e.g., Lab color coordinate system data). Thereafter, the CPU 21 converts the color-value data into a CMYK (cyan, magenta, yellow, and black) color-model data. The CMYK format is the color representation format of a recording material (i.e., colorant) that is used by the printing unit 30. The image processing unit 20 according to the present embodiment of the invention performs correction processing on the CMYK data, that is, data that is to be supplied to the printing unit 30. After the correction processing, the image processing unit 20 supplies the processed data to the printing unit 30. The image processing unit 20 has unique features in the correction processing. A more detailed explanation of the color conversion processing including the correction processing will be given later. The CPU 21 performs the processing described above in accordance with various kinds of programs stored in the ROM 22.

In addition to the programs used for the processing of the CPU 21, the ROM 22 stores two color conversion tables and correction processing data. One of the two color conversion tables, which may be hereinafter referred to as “color conversion table (1)”, is used for converting the scanner input data represented in RGB into Lab color coordinate system data. A Lab color value that corresponds to each grid point (i.e., RGB coordinate value) in an RGB three-dimensional space is stored in the color conversion table (1). The color conversion table (1) is tailored to the characteristics of the scanning unit 10 of the copying machine 1 so that each color of an original document is represented as an accurate and faithful color value (i.e., Lab value).

The other color conversion table, which may be hereinafter referred to as “color conversion table (2)”, is used for converting the Lab image data into the printing output data represented in CMYK. A CMYK value that corresponds to each grid point (i.e., Lab value) in a Lab three-dimensional space is stored in the color conversion table (2). The color conversion table (2) is tailored to the characteristics of the printing unit 30 of the copying machine 1 so that each Lab color value is outputted accurately and faithfully.

The correction processing data is data used for the correction processing described above. The correction processing data includes data that represents (i.e., defines) a primary color region in the color space (i.e., Lab three-dimensional space) of the color values. The correction processing data further includes data that represents the tone values of a primary color for change in the correction processing. One feature of the copying machine 1 according to the present embodiment of the invention lies in that the correction processing data is pre-registered into the copying machine 1 so that it can be used when copy processing is performed. A more detailed explanation of the creation of the correction processing data and the pre-storage thereof will be given later.

The RAM 23 is a storage unit that temporarily stores data such as the scanner input data supplied from the scanning unit 10, various data generated in the process of the color conversion processing, the printing output data after the correction processing, and the like.

The printing unit 30 prints an image on a print target medium on the basis of the printing output data after the correction processing, which is supplied as an output from the image processing unit 20. The printing unit 30 is provided with a print control unit and a printing mechanism, both of which are not illustrated in FIG. 1. Upon receiving the printing output data, the print control unit instructs the printing mechanism to perform printing on the basis of the received output data. In addition, the print control unit controls the operation of each component of the printing mechanism. The printing mechanism includes a photosensitive member, an electrostatic charging unit, a light exposure unit, a developing unit, an image transfer unit, and the like. The printing mechanism performs print processing on a print target medium such as a sheet of printing paper or the like on the basis of the printing output data. An image of an original document scanned by the scanning unit 10 is copied as an output of print processing performed by the printing unit 30.

The copying machine 1 that has the configuration explained above has unique features in the correction processing performed on the printing output data (printer output data). First of all, the content of the correction processing data, which is used for the unique correction processing, is explained below. The following pre-use operation is performed, for example, before shipment, to prepare the correction processing data. The prepared correction processing data is pre-stored in the ROM 22.

As a first step, a chart 2 on which a plurality of patches 3 of a primary color that will be subjected to the correction processing is printed is scanned with the use of the scanning unit 10. An example of the primary color that will be subjected to the correction processing is yellow or black. These patches 3 have depths of shade (tones) that vary from one to another. That is, a plurality of patch images of different color density is acquired as a result of scanning. A plurality of charts 2 has been prepared for various printing conditions such as the types of a print target medium (e.g., sheet type), printing methods, and the like. The scanning operation explained above is performed for each of the plurality of charts 2 for the corresponding one of the plurality of printing conditions. For example, a chart printed on recycled paper, a chart for printing under the same printing condition as that of an ordinary printed matter, and the like are scanned.

FIG. 2 is a diagram that schematically illustrates an example of the chart 2 according to an exemplary embodiment of the invention. As illustrated in FIG. 2, the plurality of patches 3 of a primary color with different depths of shade is printed on the chart 2. For example, a color is divided in a dozen or so scales ranging from the lightest one to the darkest one. The patches 3 are printed with different depths of shade each of which corresponds to the scale. The plurality of charts 2 on each of which these patches 3 are printed has been prepared as explained above.

After the scanning explained above, the scanning unit 10 generates the RGB data as a result of the color measurement of each of the plurality of patches 3 for each of the plurality of charts 2. The RGB data for each pixel (for plural positions) is obtained for each patch 3 depending on the resolution of the scanning unit 10. Thereafter, the RGB data is converted into Lab data with reference to the color conversion table (1). The average value of the respective Lab values of the pixels included in each patch 3 is calculated. The calculated average value is taken as the representative Lab value of the patch 3. The average value is calculated for each patch 3.

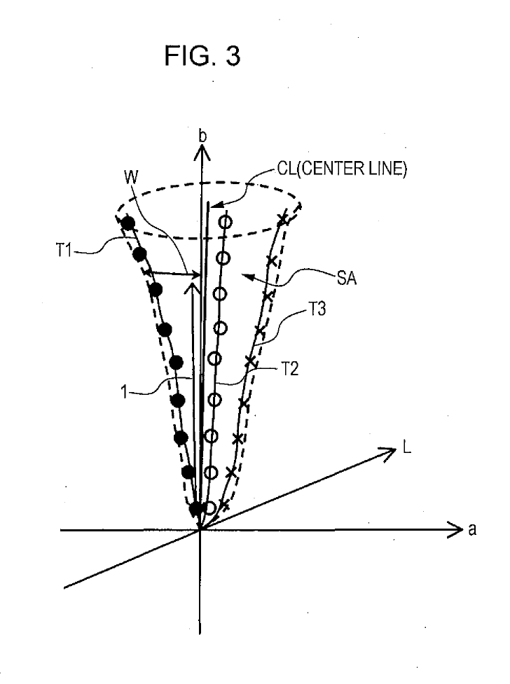

Thereafter, the Lab value of each pixel and the representative Lab value are plotted on the Lab three-dimensional color space for each patch 3 of each chart 2. FIG. 3 is a diagram that schematically illustrates an example of a Lab three-dimensional color space according to an exemplary embodiment of the invention. In the Lab three-dimensional color space illustrated in FIG. 3, each point shown by a black circle, a white circle, and an X-indication mark is a plot point of the representative Lab value. In the illustrated example, the scanning is performed for three types of the charts 2. The plot points indicated with the same mark are plotted from the patches 3 of the same chart 2. Note that the plot point for the Lab value of each pixel is not shown in the drawing. Lines T1, T2, and T3 denote approximate curves derived from the plot points of the representative Lab values for the respective charts 2.

Next, on the basis of the plot points of the representative Lab values for the respective charts 2, the center line CL of a primary color region S that is to be defined and the tone value of a primary color at each point on the center line CL is determined. For example, the center line CL is determined as follows. The coordinates of the plot points of the representative Lab values for the patches 3 of the plurality of charts 2 that correspond to one another in terms of the depth of shade are averaged. In the illustrated example of FIG. 3, the average of the coordinates of the plot points of the representative Lab values for the patches 3 of three charts 2 having the same depth of shade is found. The average coordinates are found and plotted sequentially. Then, an approximate curve that goes through these plotted average points is found. In this way, the center line CL is found. Then, a tone value for the depth of shade of the corresponding patches 3 is assigned to each plot point on the center line CL. That is, the tone value of the patches 3 used for finding the average plot point is assigned thereto.

Next, a primary color region S is defined. In order to define the primary color region S, a base primary color region OS is determined first. The base primary color region OS is a spatial domain in the Lab space in which almost all color values that should be outputted as a primary color are included. After the determination of the base primary color region OS, a removal region RS is excluded (i.e., removed or deducted) from the base primary color region OS. The removal region RS is a region in the Lab space in which a color that is close to a primary color but should not be outputted as the primary color, for example, human flesh color, exists. The primary color region S is defined as a result of the exclusion of the removal region RS from the base primary color region OS.

The base primary color region OS is explained first. In the illustrated example of FIG. 3, a primary color is assumed to be yellow. Accordingly, in the following description, yellow is taken as an example of the primary color for consistency with the drawing. A primary color of yellow usually exists at spatial positions substantially overlapping the b axis of the Lab space. For this reason, the center line CL that is found as explained above constitutes a line close to the b axis thereof. For each point on the center line CL, for example, the plot point explained above, an ellipse having its center on the point on a plane that passes through the point and is perpendicular to the b axis, that is, parallel to the L-a plane, is considered here. Each point on the center line CL as well as the radius of the long axis of the ellipse and the radius of the short axis thereof define the base primary color region OS.

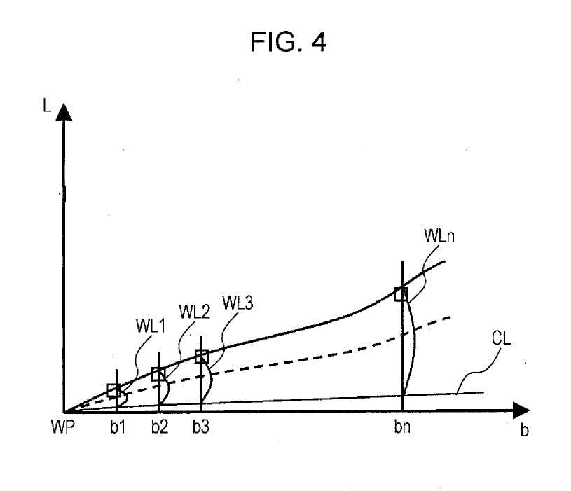

Though not illustrated in FIG. 3, the Lab values of respective pixels in each patch exist in a dispersed manner when viewed as a whole around the corresponding representative Lab value in the Lab space. Since the primary color is assumed to be yellow in this example, the distribution of the Lab values of the respective pixels is considered with respect to the L direction and the “a” direction. FIG. 4 is a diagram that schematically illustrates an example of the radius of the long axis of an ellipse and the radius of the short axis thereof according to an exemplary embodiment of the invention.

In FIG. 4, CL denotes the center line projected on the b-L plane. Each of b1, b2, . . . , and bn denotes a point on the center line projected on the b axis in perpendicular to the b axis. One Lab value that is most distant from each point on the center line when viewed in the L direction among the Lab values of pixels corresponding to the point is plotted on the b-L plane. Each square plot point in FIG. 4 denotes the plotted Lab value that is most distant from the point on the center line. The Lab values of pixels corresponding to each point on the center line mean the Lab values of pixels in a patch 3 used for finding the point on the center line. Although the position of the Lab value plotted on the b-L plane that is most distant from each point on the center line is not always above the b axis in the graph, that is, though the plotted positions of the remotest Lab values for some points on the center line may be below the b axis in the graph, to simplify explanation, it is illustrated therein that the plotted positions of the remotest Lab values for all points on the center line are above the b axis.

After the plotting of the remotest Lab values, a distance between each point on the center line and the corresponding plot point indicated by a square sign, which is most distant from the point when viewed in the L direction, is calculated (WL1, WL2, . . . , WLn).

The L-directional distance constitutes either the radius of the long axis of an ellipse or the radius of the short axis thereof for defining the base primary color region OS.

Next, the same processing as above is performed on the b-a plane. That is, a distance between each point on the center line and the corresponding plot point (colorimetric point), which is most distant from the point when viewed in the “a” direction, is calculated (Wa1, Wa2, . . . , Wan). The a-directional distance constitutes the other of the radius of the long axis of the ellipse and the radius of the short axis thereof for defining the base primary color region OS.

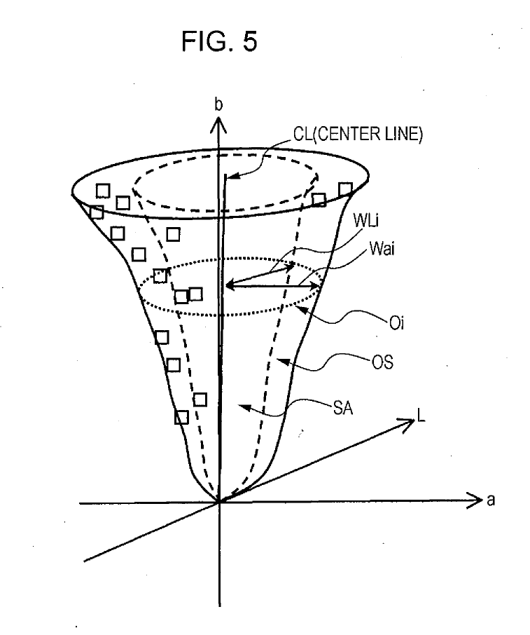

FIG. 5 is a diagram that schematically illustrates an example of a defined base primary color region OS according to an exemplary embodiment of the invention. FIG. 5 shows the base primary color region OS corresponding to an example of FIG. 3. The base primary color region OS is defined as a space occupied by a series of ovals Oi each of which has its center at the corresponding point on the center line CL. The series of ovals Oi are formed along the center line CL to define the space. The radius of the long axis of the oval Oi and the radius of the short axis thereof are denoted as WLi and Wai in the drawing. Square plot points illustrated in FIG. 5 show some of the plotted Lab values of the pixels of the patches 3. Since the radius of an ellipse is determined as explained above, almost all of the Lab values of the pixels of the patches 3 whose color has been measured by the scanning unit 10 are located inside the base primary color region OS.

In the foregoing description of an exemplary embodiment of the invention, yellow is taken as an example of the primary color. The base primary color region OS is determined in the same manner as above when the primary color is black. In such a case, a primary color of black usually exists at spatial positions substantially overlapping the L axis of the Lab space. For this reason, the center line CL that is found as explained earlier constitutes a line close to the L axis thereof. Each point on the center line CL as well as the radius of the long axis of an ellipse having its center on the point on a plane that passes through the point and is perpendicular to the L axis, that is, parallel to the b-a plane and the radius of the short axis thereof define the base primary color region OS.

As explained above, the base primary color region OS can be defined in such a manner that all of the Lab values of the pixels of the patches 3 whose color has been measured by the scanning unit 10 are included therein. The base primary color region OS defined as above is used for the determination of the primary color region S. Accordingly, the greatest effects of reproducing, in a primary color, an image part that is represented in the primary color in an original document can be expected through the correction processing, which will be explained in detail later. However, this means that the possibility of outputting, in the primary color, any color that should not be outputted as the primary color is also relatively high. In view of the above, with the definition of the maximum base primary color region that includes all of the Lab values of the pixels of the patches 3 whose color has been measured by the scanning unit 10, the base primary color region OS may be defined as a region that is smaller than the maximum base primary color region. The base primary color region OS that is smaller than the maximum base primary color region may be hereinafter referred to as “smaller-than-the-maximum base primary color region.”

A dotted region illustrated in each of FIGS. 3 and 5 indicates an average primary color region SA that is defined on the basis of the representative Lab values of the patches 3. The smaller-than-the-maximum base primary color region OS described above is defined as a region that is larger than the average primary color region SA but smaller than the maximum base primary color region OS. That is, the smaller-than-the-maximum base primary color region includes the average primary color region SA and is included in the maximum base primary color region OS. The specific size of the smaller-than-the-maximum base primary color region may be arbitrarily determined in consideration of the use/application of the copying machine 1.

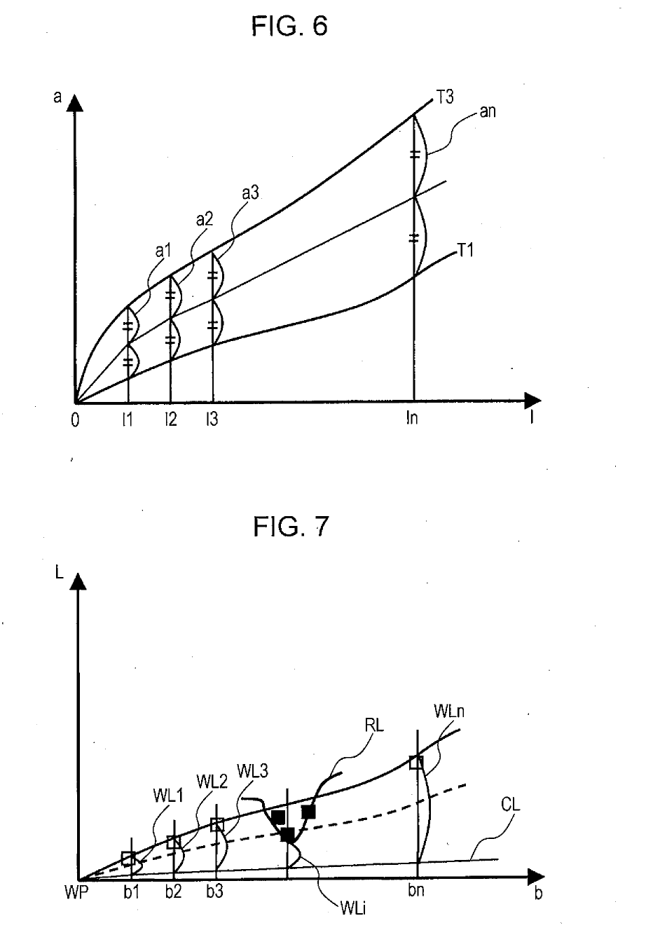

The average primary color region SA can be defined as follows. An explanation is given on the basis of the example illustrated in FIG. 3 while making reference thereto. As a first step, graphs that show the relationship between a distance 1 on the approximate curves T1, T2, and T3 mentioned earlier and the dimension elements of Lab are created. That is, three graphs that respectively represent the relationship between the distance 1 and L, the relationship between the distance 1 and a, and the relationship between the distance 1 and b are created. FIG. 6 is a diagram that schematically illustrates an example of a graph that shows the relationship between the distance 1 and a according to an exemplary embodiment of the invention. The distance 1 shows a distance measured from the origin in the Lab three-dimensional color space.

Next, one half of a difference between the maximum value of each of the dimension elements of Lab and the minimum value thereof at each distance (11, 12, 13, . . . , 1n) in each graph is acquired. The acquired value is associated with each distance 1. In the illustrated example of FIG. 6, the maximum value and the minimum value are on the approximate curves T3 and T1, respectively. As illustrated in the drawing, an a-value difference between the maximum value on the approximate curve T3 and the minimum value on the approximate curve T1 is calculated for each distance (11, 12, 13, . . . , 1n). Then, the half of the difference values denoted as a1, a2, a3, . . . , an are associated with 11, 12, 13, . . . , 1n, respectively. The same processing is performed for the graph that shows the relationship between the distance 1 and L and the graph that shows the relationship between the distance 1 and b.

Let the distances (11, 12, 13, . . . , 1n) be denoted as li. Let the values of the dimension elements of Lab associated therewith as explained above be denoted as Li, ai, and bi, respectively. Then, as a result of the processing explained above, it can be expressed that Li, ai, and bi are associated with li. For each li, the width of the average primary color region, which is denoted as Wi, is calculated using the following formula on the basis of Li, ai, and bi associated therewith.

Wi=(Li²+ai²+bi²)^{1/2}

Then, the calculated relationship between li and Wi is associated with the center line CL. That is, the width of the average primary color region SA at a point on the center line CL at which a distance from the origin is li is taken as Wi. FIG. 3 illustrates an example of the distance and the width for one point (denoted as 1 and W, respectively). The width Wi is a distance when viewed in the direction of a line normal to the center line CL at a point thereon at which the distance from the origin is li. An area within the normal-direction distance of Wi from the point on the center line CL at which the distance is li is taken as the area of the average primary color region SA. In other words, the area of the average primary color region SA is defined as an area inside a circle that has a radius of Wi and the center at the point thereon at which the distance is li on a plane normal to the center line CL. The average primary color region SA is defined as a series of the circular areas formed along the center line CL. The average primary color region SA constitutes a region that basically includes the representative Lab value of each patch 3.

In the foregoing description of an exemplary embodiment of the invention, the correction processing data is prepared with the use of the plurality of charts 2. Notwithstanding the foregoing, the correction processing data may be prepared with the use of a single chart 2. In such modified preparation of the correction processing data, the center line CL and the base primary color region OS can be defined in the same manner as explained above. However, since the center line CL is defined as the approximate curve for this single chart 2 (e.g., T1, T2, or T3), the average primary color region SA is determined in agreement with the center line CL.

Next, the removal region RS is excluded from the base primary color region OS to determine the primary color region S. First, an original document that includes an original print color(s) that should not be outputted as a primary color(s) (e.g., yellow only) when the printing unit 30 outputs a printed image is read with the use of the scanning unit 10. That is, the scanning unit 10 scans a sample of the color that should be excluded from the primary color. An example of the color that should not be outputted as the primary color is flesh color. Then, the scanning unit 10 generates the RGB data mentioned earlier for each pixel as a result of color measurement. Thereafter, the RGB data is converted into Lab data with reference to the color conversion table (1). The Lab data is plotted in the Lab space.

In the following explanation, yellow is taken as an example of the primary color. The distribution of the plotted Lab values of the respective pixels is considered with respect to the L direction and the “a” direction. FIG. 7 illustrates an example of the plotted Lab value of each pixel projected on the b-L plane. An example illustrated in FIG. 7 corresponds to the foregoing example illustrated in FIGS. 3 to 6. Specifically, FIG. 7 is the same as FIG. 4 except for the plotted points indicated by a filled square sign for the color that should be excluded from the primary color.

An exclusion curve (i.e., removal line) RL is drawn for the plotted points indicated by the black square sign for the color that should be excluded from the primary color. The curved line RL is drawn to demarcate the lower end of an exclusion range when viewed in the direction of the L axis within which the plotted points for the color that should be excluded from the primary color exist. Then, a comparison is made between WLi that defines the base primary color region OS described above and an L-directional distance of the curved line RL from the center line CL sequentially along the b axis for respective points. For each position at which the latter is smaller, the value WLi of the base primary color region OS is replaced with the L-directional distance of the curved line RL from the center line CL. In a case where there is no position at which the L-directional distance of the curved line RL from the center line CL is smaller than the original value WLi, the replacement explained above is not performed.

The same processing as above is also performed on the b-a plane for the replacement of Wai of the base primary color region OS where it is necessary. Consequently, for each position where the replacement of the values is performed, the colorimetric point of the color that should be excluded from the primary color is not included in the area of an ellipse defined by WLi and Wai. In a case where the original values WLi and Wai are not replaced with the L-directional distance of the curved line RL from the center line CL, it can be judged that no color value of the color that should be excluded from the primary color exists inside the base primary color region OS.

As a result of the replacement processing explained above, a new region that is defined by WLi and Wai subjected to the replacement processing if applicable is determined. The new region is the primary color region S, which is found by deducting the removal region RS from the base primary color region OS. If there is more than one color that should be excluded from the primary color, the exclusion of the removal region RS from the base primary color region OS is performed more than one time in the same manner as above to determine the primary color region S.

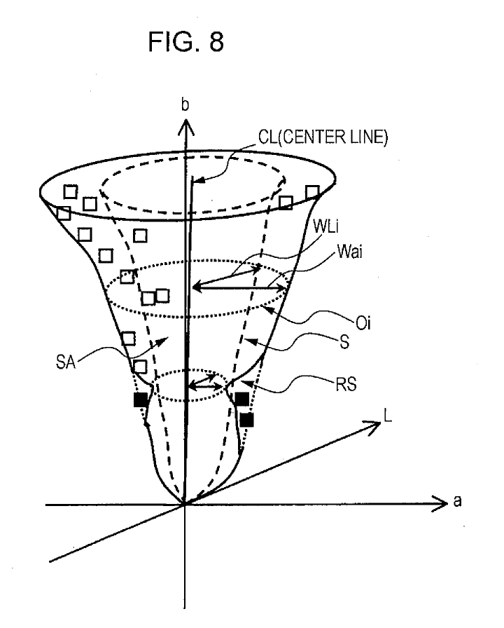

FIG. 8 is a diagram that schematically illustrates an example of a defined primary color region S according to an exemplary embodiment of the invention. The example of the primary color region S illustrated in FIG. 8 is obtained by removing the removal region RS from the base primary color region OS illustrated in FIG. 5. The primary color region S is defined in such a manner that color values for the color that should be excluded from the primary color whose plotted points are indicated by the black square sign are not included therein. In other words, at each point/position where a color value for the color that should be excluded from the primary color exists inside the base primary color region OS, the value of WLi/Wai is replaced with a smaller value as illustrated in FIG. 8.

As explained above, the primary color region S is determined by removing a region in which the color that should be excluded from the primary color exists from the base primary color region OS. The primary color region S for each primary color that is found as explained above and the depth-of-shade tone value of each point on the center line CL thereof are pre-registered in the ROM 22. As explained earlier, the base primary color region OS can be defined to have an arbitrary size that is larger than the average primary color region SA but is not larger than the maximum base primary color region OS. Whatever the size of the base primary color region OS may be, the primary color region S is determined as explained above by excluding, from the base primary color region OS, a region in which the color that should be excluded from the primary color exists. In the foregoing description of an exemplary embodiment of the invention, it is explained that the scanning unit 10 scans a sample to determine a region in the Lab space in which a color that should be excluded from a primary color exists. However, the scope of the invention is not limited to such an example. For example, pre-stored general data may be used instead of sample scanning.

In the foregoing description of an exemplary embodiment of the invention, it is explained that the entire region in which the color that should be excluded from the primary color exists is excluded from the base primary color region OS. Notwithstanding the foregoing, not all but some part of the region in which the color that should be excluded from the primary color exists may be removed from the base primary color region OS in order to define the primary color region S. When the primary color region S is defined as modified above, each of WLi and Wai takes a value that is between its original value and a value determined by the curved line RL.

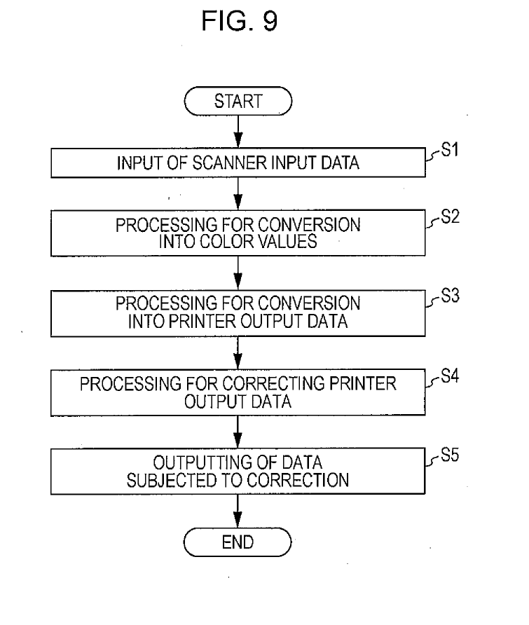

Next, the flow of processing performed by the image processing unit 20 of the copying machine 1 when an original document is copied is explained below with a focus on the correction processing explained above. FIG. 9 is a flowchart that schematically illustrates an example of the procedure of processing performed in copy processing according to an exemplary embodiment of the invention.

As a first step, image data of an original document acquired by the scanning unit 10 (i.e., scanner input data) is inputted from the scanning unit 10 (step S1). Next, since the inputted data is in an RGB format in which each pixel has an RGB gradation value as explained earlier, the data of RGB color representation is converted into one that is represented in color values (Lab) (step S2). The aforementioned color conversion table (1) is used as a lookup table for the conversion processing described above. The converted image data has a format in which each pixel has a Lab value.

Then, the image processing unit 20 further converts the image data into one that has a format available for print processing performed by the printing unit 30 (“printer output data”) (step S3). That is, the data of Lab color-value representation is converted into the data of CMYK color representation. The aforementioned color conversion table (2) is used as a lookup table for the conversion processing described above. The converted image data has a format in which each pixel has a CMYK tone value.

Next, correction processing, which is a feature of processing performed by the copying machine 1 according to the present embodiment of the invention, is performed on the printing output data (step S4). As a first step of the correction processing, it is confirmed where the color of each pixel is located in the Lab three-dimensional space with the use of the image data in the Lab format. Specifically, it is judged whether the color of each pixel is positioned inside the primary color region S defined as explained above or not. If the primary color region S has been registered in advance for more than one primary color such as Y (yellow) and K (black) as in the foregoing example, the judgment is made for the primary color region S of each primary color.

If it is judged that the color of a pixel is located inside the primary color region S, the position of the pixel is moved to the position of a point on the center line CL. Specifically, the position of the pixel is moved in a direction parallel to a plane that defines the ellipse mentioned earlier to a point of intersection at which the plane and the center line CL intersect with each other. Then, the CMYK tone value of the generated printing output data for this pixel is changed into a tone value of the primary color that has been assigned to the point (“after-the-movement point”) on the center line CL. For example, if the primary color is K, the CMYK tone value of (10, 0, 5, 98) is changed into (0, 0, 0, 100).

That is, if it is judged that the color of a pixel is located inside the primary color region S, image data is corrected so as to ensure that the color of the pixel is represented in the primary color only when an image is outputted. Correction processing data that has been prepared and registered in advance is used for the judgment and tone-value correction described above. In a case where no tone value has been assigned to the point of movement destination on the center line CL, a value is calculated by interpolation processing on the basis of points next to the point of movement destination.

In this way, correction processing is performed for each pixel whose color is located inside the pre-registered primary color region S (any of the pre-registered primary color regions S if more than one primary color regions S has been registered) so that the color thereof should be represented in the primary color.

On the other hand, if it is judged that the color of a pixel is located outside the primary color region S, the correction processing for representing the color thereof in the primary color only when an image is outputted is not performed.

Upon completing the correction of the printing output data as explained above, the image processing unit 20 outputs the printing output data after the correction processing to the printing unit 30 (step S5). Upon receiving the printing output data subjected to the correction processing, the printing unit 30 performs print processing on a predetermined print target medium on the basis of the received data. Since the correction processing is performed for each pixel whose color is located inside the pre-registered primary color region S, it follows that printing is performed for the pixel with the use of a recording material (e.g., toner) of the primary color only.

As explained in detail above, the copying machine 1 according to an exemplary embodiment of the invention reads an image of a color sample of a primary color such as the chart 2 described above and pre-defines the primary color region S of the primary color on the basis of acquired color values. When copy processing is performed, the copying machine 1 corrects image data for each pixel whose color is located inside the pre-registered primary color region S so as to ensure that the color thereof is outputted in the primary color only. In order to define the primary color region S, a region in which almost all color values that have been measured as a result of reading the sample are included is defined first. Thereafter, a region in which a color that should not be outputted as the primary color exists is excluded from the first-mentioned region for the determination of the primary color region S. With such correction processing, even when some reading error or reading variation occurs, it is possible to faithfully reproduce an image part that is represented in a primary color in an original document in the primary color and to correctly output a non-primary color part because a color that should not be outputted as the primary color, for example, human flesh color, is not included in the primary color region S. Therefore, it is possible to output a copy image that looks good and thus achieve high-quality copying.

In addition, the region in which a color that should not be outputted as the primary color exists is determined on the basis of data acquired by actually reading an original document on which the color is printed with the use of the scanning unit 10 as a removal color sample. Therefore, the removal region is recognized accurately, which makes it possible for the copying machine 1 to perform image data correction processing with high precision.

Moreover, if a part of the region in which the color that should not be outputted as the primary color exists is excluded from the first-mentioned region for the determination of the primary color region S, it is possible to balance the faithful reproduction of primary colors and the correct color output of non-primary colors, the latter of which should not be outputted as a primary color.

In the foregoing description of an exemplary embodiment of the invention, it is explained that the CPU 21 performs operation in accordance with programs as a main unit for the processing of the image processing unit 20. Notwithstanding the foregoing, the processing of the image processing unit 20 may be embodied in a variety of ways and/or with the use of various means, for example, by employing an ASIC. And the programs may be recording in a computer-readable recording medium.

The technical scope of the present invention is not limited to the explicit and implicit description of the foregoing exemplary embodiment. The scope of the invention encompasses inventive concepts that are recited in the appended claims and equivalents thereof.

The entire disclosure of Japanese Patent Application No. 2008-262175, filed Oct. 8, 2008 is expressly incorporated by reference herein.

What is claimed is:

1. An image processing apparatus that performs processing for converting image data of an original document acquired by a reading apparatus into data for an output apparatus, the image processing apparatus comprising:
a correcting section that applies a change to the image data so as to ensure that a color that is located in a predetermined region in a color space that represents color values of an image is outputted in one color of a recording material of the output apparatus; and
a corrected data outputting section that outputs the image data corrected by the correcting section,
wherein the predetermined region is defined by excluding a second region in the color space from a first region in the color space,
the first region is a region that includes each color value obtained as a result of reading a sample by means of the reading apparatus, the sample including a plurality of printed patches of the one color, the printed patches having depths of shade that differ from one to another, and
the second region is a region in which a predetermined color that should not be outputted as the one color is located.

2. The image processing apparatus according to claim 1, wherein the second region is determined on the basis of each color value that is obtained as a result of reading a sample on which an image in the predetermined color is printed by means of the reading apparatus.

3. The image processing apparatus according to claim 1, wherein the predetermined region is defined by excluding a part of the second region from the first region.

4. The image processing apparatus according to claim 1, wherein the one color is yellow; and the predetermined color that should not be outputted as the one color is flesh color.

5. A computer-readable recording medium for a recording image processing program for causing an image processing apparatus to perform processing for converting image data of an original document acquired by a reading apparatus into data for an output apparatus, the image processing program causing the image processing apparatus to execute:
applying a change to the image data so as to ensure that a color that is located in a predetermined region in a color space that represents color values of an image is outputted in one color of a recording material of the output apparatus for correction; and
outputting the corrected image data,
wherein the predetermined region is defined by excluding a second region in the color space from a first region in the color space,
the first region is a region that includes each color value obtained as a result of reading a sample by means of the reading apparatus, the sample including a plurality of printed patches of the one color, the printed patches having depths of shade that differ from one to another, and
the second region is a region in which a predetermined color that should not be outputted as the one color is located.
